(19) United States
(12) Patent Application Publication
(10) Pub. No.: US 2026/0285194 A1
(43) Pub. Date: Sep. 24, 2026

(54) ELECTRIC ROBOT, CHARGER, AND CHARGING SYSTEM

(71) Applicants: Hyundai Motor Company, Seoul (KR); Kia Corporation, Seoul (KR)

(72) Inventor: Sang Won YOON, Gyeonggi-do (KR)

(21) Appl. No.: 19/479,318

(22) PCT Filed: Dec. 14, 2023
(86) PCT No.: PCT/KR2023/020667

§ 371 Date: Oct. 27, 2025

(30) Foreign Application Priority Data
Jul. 18, 2023 (KR) 10-2023-0093303

(51) Int. Cl. B60L 58/12; B60L 53/62; B60L 53/66

(52) U.S. Cl. CPC B60L 58/12; B60L 53/62; B60L 53/66

(57) ABSTRACT

Disclosed are an electric robot, a charger, and a charging system including: a battery that is charged through a first charging terminal; a first relay for determining whether to supply power to the battery; a first communication unit for communicating with the charger, and a first controller for blocking the first relay when a voltage abnormality signal on the charger side is received.

### TECHNICAL FIELD

The present invention relates to an electric robot, charger and charging system configured to prevent power from being inappropriately supplied to a battery even when some power cutoff functions in the charging system do not operate normally.

### BACKGROUND ART

Generally, batteries have a risk of fire or explosion when subjected to strong impact or high heat, or when overcharged or overdischarged.

To prevent such risks, battery management systems (BMS: Battery Management System) and the like are connected to batteries to cut off battery power during overcharge or overdischarge, or abnormal voltage cutoff functions are applied to chargers that supply power to batteries.

When battery management systems or voltage cutoff functions of chargers operate normally, battery explosion or battery fire due to overcharge can be significantly prevented. Particularly, when both such systems and functions are provided, battery explosion or fire can be prevented even when one of them fails.

However, when both such systems and functions do not operate normally, the battery cannot be protected from overcharge and the like.

The matters described as the background art above are only for enhancing understanding of the background of the present invention, and should not be taken as acknowledging that they correspond to prior art already known to those having ordinary knowledge in this technical field.

### DETAILED DESCRIPTION OF THE INVENTION TECHNICAL PROBLEM

An object of the present invention is to provide an electric robot, charger and charging system capable of preventing power from being inappropriately supplied to a battery even when some power cutoff functions in the charging system do not operate normally.

The objects of the present invention are not limited to the objects mentioned above, and other objects not mentioned will be clearly understood by those skilled in the art from the description below.

### SOLUTION OF THE PROBLEM

An electric robot according to an embodiment of the present invention for realizing the above object comprises: a battery charged by receiving power from a charger through a first charging terminal; a first relay disposed at one end of the first charging terminal and configured such that power is selectively supplied to the battery according to connection or disconnection state; a first communicator configured to perform communication with the charger; and a first controller configured to disconnect the first relay when the charger-side voltage abnormality signal is received from the charger through the first communicator, or when voltage of the battery exceeds a predetermined voltage in a state where no charging request is generated.

For example, the first controller may disconnect the first relay when the charger-side voltage abnormality signal is received in a state where power is being supplied to the battery through the first charging terminal.

For example, the first controller may disconnect the first relay when the charger-side voltage abnormality signal is received through the first communicator in a state where a second relay provided in the charger and configured to determine whether to supply power to the first charging terminal according to connection and disconnection state is connected.

For example, the first controller may disconnect the first relay when the charger-side voltage abnormality signal is received through the first communicator in a state where power of the battery is not cut off.

For example, the first controller may output a battery-side voltage abnormality signal through the first communicator when the voltage of the battery exceeds the predetermined voltage in the state where no charging request is generated.

For example, the first controller may transmit to the charger through the first communicator a control signal for causing a second relay provided in the charger and configured to determine whether to supply power to the first charging terminal according to connection and disconnection state to be disconnected, when the voltage of the battery exceeds the predetermined voltage in the state where no charging request is generated.

For example, the electric robot according to an embodiment of the present invention may further comprise a battery management device connected to the battery and configured to cut off power of the battery when the voltage of the battery exceeds the predetermined voltage in the state where no charging request is generated, or when the charger-side voltage abnormality signal is received through the first communicator.

For example, the first controller may control the robot to stop operation when the voltage of the battery exceeds the predetermined voltage in the state where no charging request is generated or when the charger-side voltage abnormality signal is received through the first communicator.

For example, the first relay may be disposed between the battery and the first charging terminal.

A charger according to an embodiment of the present invention for realizing the above object comprises: a second relay disposed at one end of a second charging terminal configured to supply power to an electric robot having a first controller configured to control connection or disconnection state of a first relay such that power received through a first charging terminal is selectively supplied to a battery, the second relay configured to determine whether to supply power to the electric robot according to connection and disconnection state; a second communicator configured to perform communication with a first communicator provided in the electric robot; and a second controller configured to disconnect the second relay when an electric robot-side voltage abnormality signal is received from the electric robot through the second communicator, or when internal voltage exceeds a predetermined voltage.

For example, the second controller may disconnect the second relay when the electric robot-side voltage abnormality signal is received through the second communicator while power is being supplied to the electric robot.

For example, the second controller may disconnect the second relay when the electric robot-side voltage abnormality signal is received through the second communicator in a state where the first relay is connected.

For example, the second controller may output the charger-side voltage abnormality signal through the second communicator when the internal voltage of the charger exceeds the predetermined voltage.

For example, the second controller may transmit to the electric robot through the second communicator a control signal for causing the first relay to be disconnected when the internal voltage of the charger exceeds the predetermined voltage.

A charging system according to an embodiment of the present invention for realizing the above object comprises: an electric robot including a battery charged by receiving power from a charger through a first charging terminal and a first relay disposed at one end of the first charging terminal and configured to determine whether to supply power to the battery according to connection or disconnection state, the electric robot configured to disconnect the first relay when the charger-side voltage abnormality signal is received from the charger, or when voltage of the battery exceeds a predetermined voltage in a state where no charging request is generated; and a charger including a second relay disposed at one end of a second charging terminal configured to supply power to the electric robot and configured to determine whether to supply power to the electric robot according to connection and disconnection state, the charger configured to disconnect the second relay when an electric robot-side voltage abnormality signal is received from the electric robot, or when internal voltage exceeds a predetermined voltage.

### EFFECTS OF THE INVENTION

According to various embodiments of the present invention as described above, power can be prevented from being inappropriately supplied to a battery even when some power cutoff functions in the charging system do not operate normally, thereby enabling protection of the battery from explosion, fire and the like.

The effects obtainable from the present invention are not limited to the effects mentioned above, and other effects not mentioned will be clearly understood by those having ordinary knowledge in the technical field to which the present invention belongs from the description below.

### BRIEF DESCRIPTION OF DRAWINGS

FIG. 1 is a diagram showing configuration of a charging system according to an embodiment of the present invention.

FIG. 2 is a diagram for explaining a process in which an electric robot according to an embodiment of the present invention performs abnormal voltage cutoff control for battery protection.

FIG. 3 is a diagram for explaining a process in which a charger according to an embodiment of the present invention performs abnormal voltage cutoff control for battery protection.

FIG. 4 is a sequence diagram when battery-side voltage is abnormal in a charging system according to an embodiment of the present invention.

FIG. 5 is a sequence diagram when charger-side voltage is abnormal in a charging system according to an embodiment of the present invention.

### MODES FOR CARRYING OUT THE INVENTION

Specific structural or functional descriptions of embodiments of the present invention disclosed in this specification or application are exemplified only for the purpose of describing embodiments according to the present invention, and embodiments according to the present invention may be implemented in various forms and should not be interpreted as being limited to the embodiments described in this specification or application.

Since embodiments according to the present invention can be subjected to various modifications and can have various forms, specific embodiments are illustrated in the drawings and described in detail in this specification or application. However, this is not intended to limit embodiments according to the concept of the present invention to specific disclosed forms, but should be understood to include all modifications, equivalents, and substitutes included in the spirit and technical scope of the present invention.

Unless defined otherwise, all terms used herein, including technical or scientific terms, have the same meaning as commonly understood by one of ordinary skill in the art to which the present invention belongs. Terms such as those defined in commonly used dictionaries should be interpreted as having a meaning consistent with the meaning they have in the context of the related art, and unless explicitly defined in this specification, they are not interpreted in an ideal or excessively formal sense.

Hereinafter, embodiments disclosed in this specification will be described in detail with reference to the accompanying drawings, and identical or similar components will be assigned the same reference numbers regardless of drawing symbols, and overlapping descriptions thereof will be omitted.

In the description of the following embodiments, the term “predetermined” means that the numerical value of a parameter is determined in advance when the parameter is used in a process or algorithm. The numerical value of the parameter may be set when the process or algorithm starts or may be set during a section in which the process or algorithm is performed, according to embodiments.

The suffixes “module” and “unit” for components used in the following description are given or used interchangeably considering only the ease of writing the specification, and do not have meanings or roles that are distinguished from each other by themselves.

In describing the embodiments disclosed in this specification, detailed descriptions of related known technologies are omitted when it is determined that they may obscure the gist of the embodiments disclosed in this specification. Additionally, the accompanying drawings are only for easily understanding the embodiments disclosed in this specification, and the technical ideas disclosed in this specification are not limited by the accompanying drawings, and should be understood to include all modifications, equivalents, and substitutes included in the spirit and technical scope of the present invention.

Terms including ordinal numbers such as first, second, etc. may be used to describe various components, but the components are not limited by the terms. The terms are used only for the purpose of distinguishing one component from another component.

When a component is referred to as being “connected” or “coupled” to another component, it should be understood that it may be directly connected or coupled to the other component, but other components may exist in between. On the other hand, when a component is referred to as being “directly connected” or “directly coupled” to another component, it should be understood that no other components exist in between.

Singular expressions include plural expressions unless the context clearly indicates otherwise.

In this specification, terms such as “comprise” or “have” are intended to designate that features, numbers, steps, operations, components, parts, or combinations thereof described in the specification exist, and should be understood as not excluding in advance the existence or addition possibility of one or more other features, numbers, steps, operations, components, parts, or combinations thereof.

Additionally, Unit or Control Unit included in names such as Motor Control Unit (MCU), Hybrid Control Unit (HCU), etc. are terms widely used in naming control devices (Controllers) that control specific functions of vehicles, and do not mean generic function units.

A controller may include a communication device that communicates with other controllers or sensors for control of responsible functions, memory that stores operating systems, logic commands, input/output information, etc., and one or more processors that perform judgments, calculations, decisions, etc. necessary for responsible function control.

A charging system according to an embodiment of the present invention proposes that connection between charging terminals can be released through communication between an electric robot and a charger even when both the voltage cutoff function of the battery and the voltage cutoff function of the charger do not operate normally in an abnormal voltage state, thereby effectively protecting the battery from abnormal voltage.

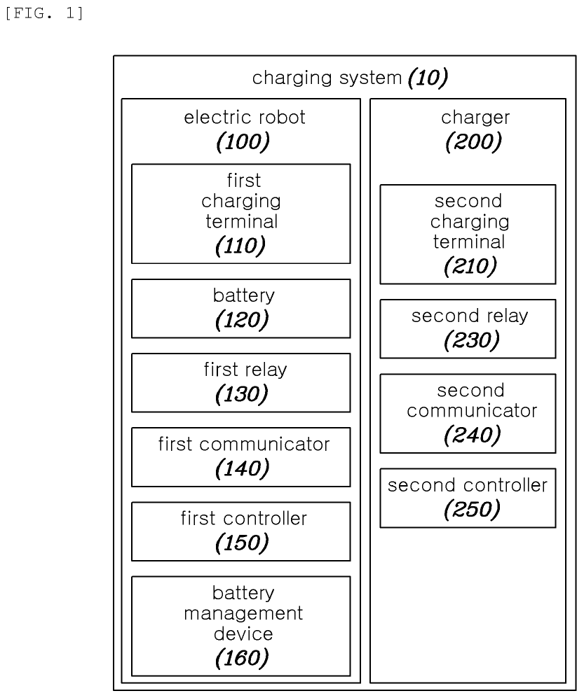

Hereinafter, the configuration of a charging system according to an embodiment of the present invention and the electric robot and charger constituting it will be described first with reference to FIG. 1.

FIG. 1 is a diagram showing configuration of a charging system according to an embodiment of the present invention.

Referring to FIG. 1, a charging system 10 according to an embodiment of the present invention includes an electric robot 100 and a charger 200. However, FIG. 1 shows mainly components related to the description of an embodiment of the present invention, and it is of course possible that an actual charging system may be implemented including more or fewer components than this. Each configuration will be described in detail below.

First, the electric robot 100 may include a first charging terminal 110, a battery 120, a first relay 130, a first communicator 140, a first controller 150, and a battery management device 160.

The battery 120 may be charged by receiving power from the charger 200 through the first charging terminal 110, and may supply the charged power for operation of the electric robot 100.

The first relay 130 is disposed at one end of the first charging terminal 110, and may selectively supply power to the battery 120 according to connection or disconnection state. More specifically, when the first relay 130 is in a connected state, power output from the charger 200 may be supplied to the battery through the first charging terminal 110, and when the first relay 130 is in a released state, supply of power output from the charger 200 may be cut off.

For this purpose, the first relay 130 may be disposed between the battery 120 and the first charging terminal 110.

The first communicator 140 performs communication with the charger 200, and may receive or transmit signals such as voltage abnormality signals, relay control signals, etc.

The first controller 150 controls the first relay 130 and the first communicator 140, and more specifically, may disconnect the first relay 130 when a charger 200-side voltage abnormality signal is received from the charger 200 through the first communicator 140.

Particularly, the first controller 150 may disconnect the first relay 130 when the charger 200-side voltage abnormality signal is received in a state where power is being supplied to the battery 120 through the first charging terminal 110, thereby preventing the battery 120 from being overcharged.

Furthermore, the first controller 150 may disconnect the first relay 130 when the charger 200-side voltage abnormality signal is received through the first communicator 140 in a state where a second relay 230 provided in the charger 200 and configured to determine whether to supply power to the first charging terminal 110 according to connection and disconnection state is connected.

Through this, it becomes possible to prevent abnormal voltage from being applied to the battery 120 even when an abnormality occurs on the charger 200 side but the abnormal voltage cutoff function of the charger 200 does not operate normally.

Additionally, the first controller 150 may disconnect the first relay 130 when the charger 200-side voltage abnormality signal is received through the first communicator 140 in a state where power of the battery 120 is not cut off.

Through this, it becomes possible to prevent abnormal voltage from being applied to the battery 120 even when an abnormality occurs on the charger 200 side but the power cutoff function of the battery 120 does not operate normally.

Particularly, according to an embodiment of the present invention, by preventing power of the charger 200 from being supplied to the battery 120 through disconnection of the first relay 130, it becomes possible to protect the battery 120 even when both the abnormal voltage cutoff function of the charger 200 and the power cutoff function of the battery 120 do not operate normally.

Meanwhile, the first controller 150 may disconnect the first relay 130 not only when an abnormality occurs on the charger 200 side, but also when voltage of the battery 120 exceeds a predetermined voltage in a state where no charging request is generated.

Additionally, the first controller 150 may output a battery 120-side voltage abnormality signal through the first communicator 140 when voltage of the battery exceeds a predetermined voltage in a state where no charging request is generated, and the output voltage abnormality signal may be transmitted to the charger 200 or a control device (not shown) for controlling the electric robot 100.

Particularly, the first controller 150 may transmit to the charger 200 through the first communicator 140 a control signal for causing a second relay 230 provided in the charger 200 and configured to determine whether to supply power to the first charging terminal 110 according to connection and disconnection state to be disconnected, when voltage of the battery 120 exceeds a predetermined voltage in a state where no charging request is generated. The charger 200 that has received such a control signal can cut off power supply to the battery 120 by disconnecting the second relay 230.

Meanwhile, the battery management device 160 is connected to the battery 120, and may perform a function of cutting off power of the battery 120 when voltage of the battery 120 exceeds a predetermined voltage in a state where no charging request is generated, or when the charger 200-side voltage abnormality signal is received through the first communicator 140. Such a battery management device 160 may also be expressed as BMS (Battery Management System). Overcharge of the battery 120 can be primarily prevented through the power cutoff function of the battery 120 by the battery management device 160, and according to an embodiment of the present invention, the battery 120 may also be protected through disconnection of the first relay 130 even when the power cutoff function of the battery management device 160 does not operate normally.

Meanwhile, the first controller 150 may control the electric robot 100 to stop operation when voltage of the battery exceeds a predetermined voltage in a state where no charging request is generated or when the charger-side voltage abnormality signal is received through the first communicator, thereby preventing additional damage.

Meanwhile, in an embodiment of the present invention, the charger 200 may include a second charging terminal 210, a second relay 230, a second communicator 240, and a second controller 250.

The charger 200 may supply power supplied from grid power, etc. to the electric robot 100, and may perform power conversion, etc. for this purpose.

For this purpose, the second charging terminal 210 may be connected to the first charging terminal 110 of the electric robot 100, and may serve as a power output terminal.

The second relay 230 is disposed at one end of the second charging terminal 210 that supplies power to the electric robot 100, and may determine whether to supply power to the electric robot 100 according to connection and disconnection state. More specifically, when the second relay 230 is in a connected state, power may be supplied to the electric robot 100, particularly to the battery 120, through the second charging terminal 210, and when the second relay 230 is in a disconnected state, power supply to the electric robot 100 may be cut off.

For example, the second relay 230 may be disposed between an input terminal of grid power and the second charging terminal within the charger 200.

The second communicator 240 performs communication with the electric robot 100, and particularly may exchange voltage abnormality signals, control signals, etc. with the first communicator 140 of the electric robot 100.

The second controller 250 controls the second relay 230 and the second communicator 240, and a more specifically may disconnect the second relay 230 when an electric robot 100-side voltage abnormality signal is received from the electric robot 100 through the second communicator 240.

The second controller 250 may also disconnect the second relay 230 when voltage inside the charger 200 exceeds a predetermined voltage.

Particularly, the second controller 250 may disconnect the second relay 230 when the electric robot 100-side voltage abnormality signal is received through the second communicator 240 while power is being supplied to the electric robot 100, thereby preventing abnormal voltage from being applied to the electric robot 100, particularly to the battery 120 of the electric robot 100.

Furthermore, the second controller 250 may disconnect the second relay 230 when the electric robot 100-side voltage abnormality signal is received through the second communicator 240 in a state where the first relay 130 provided in the electric robot 100 and configured to determine whether to supply power to the battery 120 in the electric robot 100 according to connection or disconnection state is connected, thereby preventing abnormal voltage from being applied to the battery 120 of the electric robot 100 even when control for abnormal voltage cutoff is not performed on the electric robot 100 side.

Additionally, the second controller 250 may output a charger 200-side voltage abnormality signal through the second communicator 240 when voltage inside the charger 200 exceeds a predetermined voltage, and the output voltage abnormality signal may be transmitted to the electric robot 100 or a control device (not shown) for controlling the electric robot 100.

Furthermore, the second controller 250 may transmit to the electric robot 100 through the second communicator 240 a control signal for causing the first relay 130 provided in the electric robot 100 and configured to determine whether to supply power to the battery 120 in the electric robot 100 according to connection or disconnection state to be disconnected when voltage inside the charger 200 exceeds a predetermined voltage. The electric robot 100 that has received such a control signal can prevent abnormal voltage from being applied to the battery 120 by disconnecting the first relay 130.

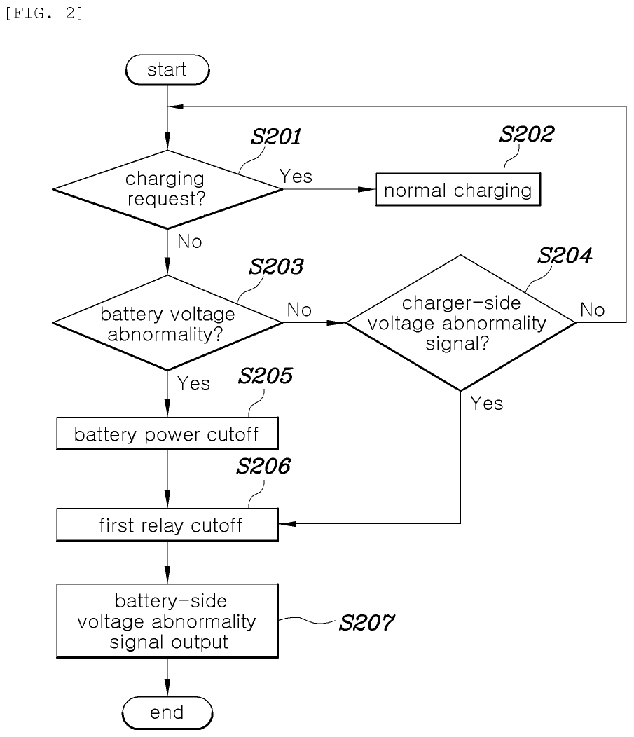

Hereinafter, with reference to FIG. 2, an abnormal voltage cutoff control process performed by an electric robot according to an embodiment of the present invention for battery protection will be described.

FIG. 2 is a diagram for explaining a process in which an electric robot according to an embodiment of the present invention performs abnormal voltage cutoff control for battery protection.

Referring to FIG. 2, when a charging request is generated (Yes in step S201), the battery 120 is normally charged, but when no charging request is generated (No in step S201) and abnormal voltage occurs on the battery 120 side, such as when voltage of the battery 120 exceeds a predetermined voltage (Yes in step S203), the battery management device 160 cuts off power of the battery 120, and the first controller 150 disconnects the first relay 130 to prevent abnormal voltage from being applied to the battery 120.

Additionally, in this case (Yes in step S203), the first controller 150 may output a battery 120-side voltage abnormality signal through the first communicator 140 in step S207.

Meanwhile, even when no abnormal voltage occurs on the battery 120 side (No in step S203), the first controller 150 may disconnect the first relay 130 when the charger 200-side voltage abnormality signal is received through the first communicator 140 (Yes in step S204), thereby preventing abnormal voltage from being applied to the battery 120 even when the abnormal voltage cutoff functions of the charger 200 and the battery management device 160 do not operate normally.

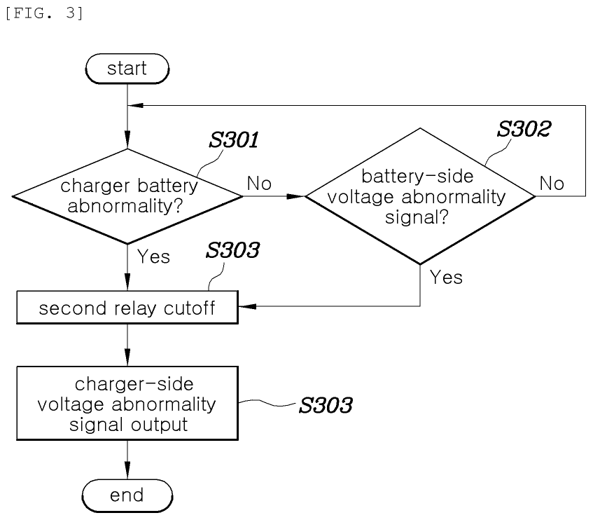

Next, with reference to FIG. 3, a process in which the charger 200 according to an embodiment of the present invention performs abnormal voltage cutoff control for battery protection will be described.

FIG. 3 is a diagram for explaining a process in which a charger according to an embodiment of the present invention performs abnormal voltage cutoff control for battery protection.

Referring to FIG. 3, when abnormal voltage occurs on the charger 200 side (Yes in step S301), the second controller 250 may prevent abnormal voltage from being applied to the battery 120 by disconnecting the second relay 230, and particularly, may prevent abnormal voltage from being applied to the battery 120 even when the abnormal voltage cutoff functions of the battery management device 160 and the first controller 150 do not operate normally.

Additionally, the second controller 250 may output a charger 200-side voltage abnormality signal in this case (Yes in step S301) in step S303.

Meanwhile, even when no abnormal voltage occurs on the charger 200 side (No in step S301), the second controller 250 may disconnect the second relay 230 when receiving a voltage abnormality signal from the battery 120 side through the second communicator 240, thereby preventing abnormal voltage from being applied to the battery 120.

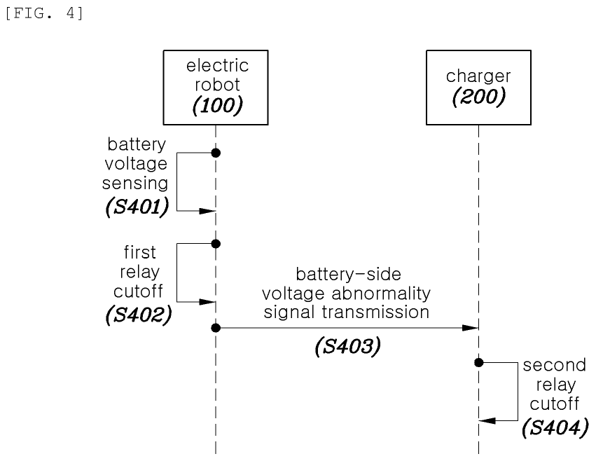

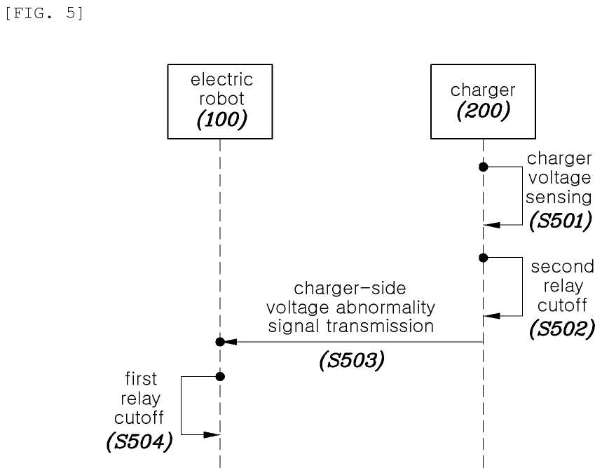

Hereinafter, with reference to FIGS. 4 to 5, an entire charging system that performs abnormal voltage cutoff functions through the electric robot 100 and the charger 200 will be described.

First, FIG. 4 is a sequence diagram when battery-side voltage is abnormal in a charging system according to an embodiment of the present invention.

Referring to FIG. 4, the electric robot 100 may determine whether abnormal voltage occurs on the battery 120 side through battery 120 sensing in step S401, and when abnormal voltage occurs on the battery 120 side, may protect the battery 120 by disconnecting the first relay 130 in step S402.

In this case, the electric robot 100 may transmit a battery-side voltage abnormality signal to the charger 200 in step S403, and the charger 200 that receives this may disconnect the second relay 230. Through this, even when functions for battery protection are not properly performed in the electric robot 100, such as when the first relay 130 is not disconnected, the battery 120 can be protected through voltage cutoff on the charger 200 side.

Next, FIG. 5 is a sequence diagram when charger-side voltage is abnormal in a charging system according to an embodiment of the present invention.

Referring to FIG. 5, the charger 200 may determine whether abnormal voltage occurs on the charger 200 side through self voltage sensing in step S501, and when abnormal voltage occurs, may prevent abnormal voltage from being applied to the battery 120 by disconnecting the second relay 230.

Additionally, the charger 200 may transmit a charger 200-side voltage abnormality signal to the electric robot 100, and the electric robot 100 that receives this may disconnect the first relay 130 in step S504. Through this, even when functions for battery protection are not properly performed in the charger 200, such as when the second relay 230 is not disconnected, the battery 120 can be protected by cutting off power supply to the battery 120.

According to various embodiments of the present invention as described above, power can be prevented from being inappropriately supplied to a battery even when some power cutoff functions in the charging system do not operate normally, thereby enabling protection of the battery from explosion, fire, and the like.

Although the present invention has been shown and described with respect to specific embodiments as described above, it will be apparent to those having ordinary knowledge in the art that the present invention may be variously improved and changed within the scope that does not depart from the technical spirit of the present invention provided by the following claims.

### DESCRIPTION OF REFERENCE NUMERALS

10: charging system
100: electric robot
200: charger

1. An electric robot comprising:
a battery charged by receiving power from a charger through a first charging terminal;
a first relay disposed at one end of the first charging terminal and configured such that power is selectively supplied to the battery according to connection or disconnection state;
a first communicator configured to perform communication with the charger; and
a first controller configured to disconnect the first relay when the charger-side voltage abnormality signal is received from the charger through the first communicator, or when voltage of the battery exceeds a predetermined voltage in a state where no charging request is generated.

2. The electric robot of claim 1, wherein the first controller is configured to disconnect the first relay when the charger-side voltage abnormality signal is received in a state where power is being supplied to the battery through the first charging terminal.

3. The electric robot of claim 1, wherein the first controller is configured to disconnect the first relay when the charger-side voltage abnormality signal is received through the first communicator in a state where a second relay provided in the charger and configured to result whether to supply power to the first charging terminal according to connection and disconnection state is connected.

4. The electric robot of claim 1, wherein the first controller is configured to disconnect the first relay when the charger-side voltage abnormality signal is received through the first communicator in a state where power of the battery is not cut off.

5. The electric robot of claim 1, wherein the first controller is configured to output a battery-side voltage abnormality signal through the first communicator when the voltage of the battery exceeds the predetermined voltage in the state where no charging request is generated.

6. The electric robot of claim 1, wherein the first controller is configured to transmit a control signal for causing a second relay provided in the charger and configured to result whether to supply power to the first charging terminal according to connection and disconnection state to be disconnected to the charger through the first communicator, when the voltage of the battery exceeds the predetermined voltage in the state where no charging request is generated.

7. The electric robot of claim 1, further comprising a battery management device connected to the battery and configured to cut off power of the battery when the voltage of the battery exceeds the predetermined voltage in the state where no charging request is generated, or when the charger-side voltage abnormality signal is received through the first communicator.

8. The electric robot of claim 1, wherein the first controller is configured to control the robot to stop operation when the voltage of the battery exceeds the predetermined voltage in the state where no charging request is generated or when the charger-side voltage abnormality signal is received through the first communicator.

9. The electric robot of claim 1, wherein the first relay is disposed between the battery and the first charging terminal.

10. A charger comprising:
a second relay disposed at one end of a second charging terminal configured to supply power to an electric robot having a first controller configured to control connection or disconnection state of a first relay such that power received through a first charging terminal is selectively supplied to a battery, the second relay configured to result whether to supply power to the electric robot according to connection and disconnection state;
a second communicator configured to perform communication with a first communicator provided in the electric robot; and
a second controller configured to disconnect the second relay when an electric robot-side voltage abnormality signal is received from the electric robot through the second communicator, or when internal voltage of the charger exceeds a predetermined voltage.

11. The charger of claim 10, wherein the second controller is configured to disconnect the second relay when the electric robot-side voltage abnormality signal is received through the second communicator while power is being supplied to the electric robot.

12. The charger of claim 10, wherein the second controller is configured to disconnect the second relay when the electric robot-side voltage abnormality signal is received through the second communicator in a state where the first relay is connected.

13. The charger of claim 10, wherein the second controller is configured to output the charger-side voltage abnormality signal through the second communicator when the internal voltage of the charger exceeds the predetermined voltage.

14. The charger of claim 10, wherein the second controller is configured to transmit a control signal for causing the first relay to be disconnected to the electric robot through the second communicator when the internal voltage of the charger exceeds the predetermined voltage.

15. A charging system comprising:
an electric robot including a battery charged by receiving power from a charger through a first charging terminal and a first relay disposed at one end of the first charging terminal and configured to result whether to supply power to the battery according to connection or disconnection state, the electric robot configured to disconnect the first relay when the charger-side voltage abnormality signal is received from the charger, or when voltage of the battery exceeds a predetermined voltage in a state where no charging request is generated; and
a charger including a second relay disposed at one end of a second charging terminal configured to supply power to the electric robot and configured to result whether to supply power to the electric robot according to connection and disconnection state, the charger configured to disconnect the second relay when an electric robot-side voltage abnormality signal is received from the electric robot, or when internal voltage exceeds a predetermined voltage.
